(19) United States
(12) Patent Application Publication
(10) Pub. No.: US 2026/0059818 A1
(43) Pub. Date: Feb. 26, 2026

(54) TRANSISTOR AND METHOD FOR MANUFACTURING SAME

(71) Applicant: Microchip Technology Incorporated, Chandler, AZ (US)

(72) Inventors: Sundar Babu Isukapati, Gilbert, AZ (US); Bruce Odekirk, Portland, OR (US); Shesh Mani Pandey, Bentonville, AR (US); George Dorman, Chandler, AZ (US)

(73) Assignee: Microchip Technology Incorporated, Chandler, AZ (US)

(21) Appl. No.: 19/058,725

(22) Filed: Feb. 20, 2025

Related U.S. Application Data
(60) Provisional application No. 63/687,121, filed on Aug. 26, 2024.

(51) Int. Cl. H10D 62/60; H10D 62/10; H10D 62/17; H10D 64/23

(52) U.S. Cl. CPC H10D 62/60; H10D 62/124; H10D 62/221; H10D 64/252

(57) ABSTRACT

A transistor comprising a first dopant layer formed within an epi layer formed within a substrate. A second dopant layer having a lower lateral well extension formed within the first dopant layer. A third dopant layer formed within the first dopant layer. A fourth dopant layer formed within the first dopant layer and over the second dopant layer. A fifth dopant layer formed within the first dopant layer. A gap formed between an end of the fifth dopant layer and an end of the first fourth dopant layer. A gate contact operatively connected to the fourth dopant layer. A source contact operatively connected to the fifth dopant layer.

### CROSS-REFERENCE TO RELATED APPLICATION

The present application claims priority to U.S. Provisional Patent Application No. 63/687,121 filed on Aug. 26, 2024, the contents of which are hereby incorporated by reference in their entirety.

### TECHNICAL FIELD

The present disclosure relates generally to transistors, and more specifically to Junction Field Effect Transistors and methods for manufacturing same to improve the performance of the transistor.

### SUMMARY

According to an aspect of one or more examples, there is provided a transistor that may include a substrate, an epi layer formed within the substrate, a first dopant layer formed within the epi layer, a first dopant layer formed within the epi layer, a second dopant layer having a lower lateral well extension formed within the first dopant layer, a third dopant layer formed within the first dopant layer, a fourth dopant layer formed within the first dopant layer and over the second dopant layer, a fifth dopant layer formed within the first dopant layer, wherein the fifth dopant layer extends over a first portion of the lower lateral well extension, a gap formed between an end of the fifth dopant layer and an end of the fourth dopant layer, wherein the gap extends over a second portion of the lower lateral well extension, a gate contact operatively connected to the fourth dopant layer, and a source contact operatively connected to the fifth dopant layer. The fifth dopant layer may be operatively connected to the third dopant layer. The substrate may comprise a first concentration of the first type dopant. The epi layer may comprise a second concentration of the first type dopant. The first concentration may be greater than the second concentration. The first dopant layer may comprise a third concentration of the first type dopant. The second dopant layer and the third dopant layer may comprise a fourth concentration of a second type dopant. The fourth dopant layer may comprise a fifth concentration of the second type dopant. The fifth dopant layer may comprise a sixth concentration of the first type dopant. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided method of manufacturing a transistor. The method may include providing a substrate, forming an epi layer within the substrate, implanting a first dopant layer into the epi layer, implanting a second dopant layer having a lower lateral well extension into the first dopant layer, implanting a third dopant layer into the first dopant layer, implanting a fourth dopant layer into the first dopant layer and over the second dopant layer, implanting a fifth dopant layer into the first dopant layer wherein the fifth dopant layer extends over a first portion of the lower lateral well extension, forming a gap between an end of the fifth dopant layer and an end of the fourth dopant layer, wherein the gap extends over a second portion of the lower lateral well extension, forming a gate contact operatively connected to the fourth dopant layer, and forming a source contact operatively connected to the fifth dopant layer. The fifth dopant layer may be operatively connected to the third dopant layer. The substrate may comprise a first concentration of the first type dopant. The epi layer may comprise a second concentration of the first type dopant. The first concentration may be greater than the second concentration. The first dopant layer may comprise a third concentration of the first type dopant. The second dopant layer and the third dopant layer may comprise a fourth concentration of a second type dopant. The fourth dopant layer may comprise a fifth concentration of the second type dopant. The fifth dopant layer may comprise a sixth concentration of the first type dopant. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 shows an illustration of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

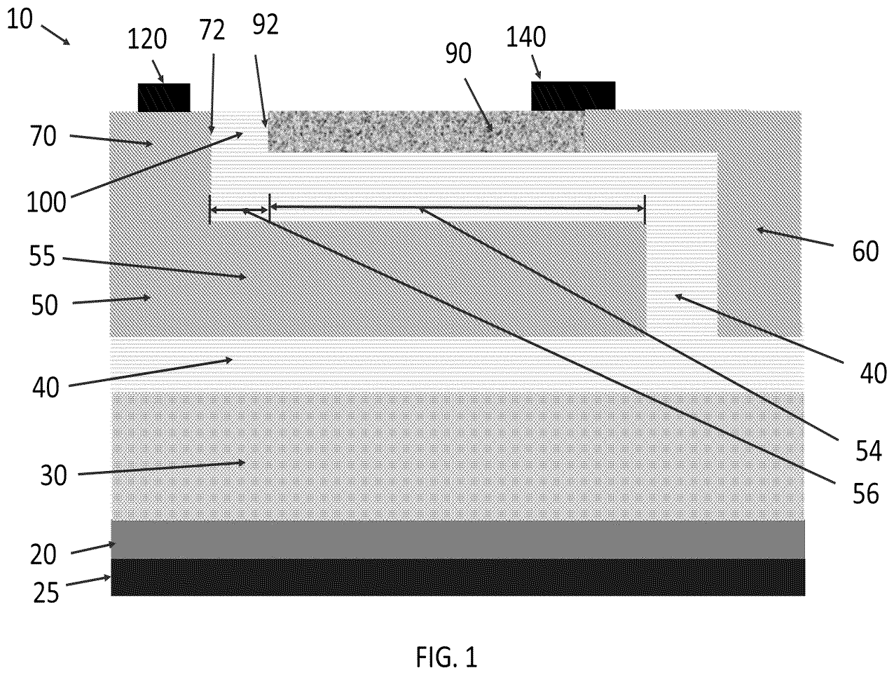

FIG. 1 shows an illustration of a transistor 10 according to one or more examples. Transistor 10 may represent, and may be called a junction field-effect transistor, without limitation. The example transistor 10 (junction field-effect transistor) of FIG. 1 includes a substrate 20. The substrate 20 shown in FIG. 1 may have a first concentration of a first type dopant, e.g., 5E18 (i.e. 5×10¹⁸). A drain contact 25 may be formed at a first side of the substrate 20. The example transistor 10 (junction field-effect transistor) of FIG. 1 may include an epi layer 30 formed within the substrate 20 at a second side of the substrate 20. The second side of the substrate 20 is opposite the first side of the substrate 20 where the drain contact 25 was formed. The epi layer 30 may comprise a second concentration of the first type dopant, wherein the first concentration of first type dopant in the substrate 20 is greater than the second concentration of first type dopant in the epi layer 30. The example transistor 10 (junction field-effect transistor) of FIG. 1 may include a first dopant layer 40 formed within the epi layer 30. The first dopant layer 40 may comprise a third concentration of the first type dopant. The example transistor 10 (junction field-effect transistor) of FIG. 1 may include a second dopant layer 50 having a lower lateral well extension 55 formed within the first dopant layer 40. The example transistor 10 (junction field-effect transistor) of FIG. 1 may include a third dopant layer 60 formed within the first dopant layer 40. The second dopant layer 50 and the third dopant layer 60 may comprise a fourth concentration of a second type dopant that may have a peak doping in the range 1E17 to 5E18. The example transistor 10 (junction field-effect transistor) of FIG. 1 may include a fourth dopant layer 70 formed within the first dopant layer 40 and over the second dopant layer 50. The fourth dopant layer 70 may comprise a fifth concentration of the second type dopant. The example transistor 10 (junction field-effect transistor) of FIG. 1 may include a fifth dopant layer 90 formed within the first dopant layer 40. The fifth dopant layer 90 may extend over a first portion 54 of the lower lateral well extension 55. The fifth dopant layer 90 may be operatively connected to the third dopant layer 60. The fifth dopant layer 90 may comprise a sixth concentration of the first type dopant. The example transistor 10 (junction field-effect transistor) of FIG. 1 may include a planar surface over the fourth dopant layer 70 and the fifth dopant layer 90. The example transistor 10 (junction field-effect transistor) of FIG. 1 may include a gap 100 formed between an end 92 of the fifth dopant layer 90 and an end 72 of the fourth dopant layer 70. The gap 100 may be formed over a second portion 56 of the lower lateral well extension 55. The example transistor 10 (junction field-effect transistor) of FIG. 1 may include a gate contact 120 operatively connected to the fourth dopant layer 70. The gate contact 120 may be made from a metal, polysilicon, or other suitable material. The example transistor 10 (junction field-effect transistor) of FIG. 1 may include a source contact 140 operatively connected to the fifth dopant layer 90. The source contact 140 may be made from a metal, polysilicon, or other suitable material. When a gate-to-source voltage is applied to the transistor 10 (junction field-effect transistor) of FIG. 1, current flows through a channel created within the gap 100 and between the lower lateral well extension 55 and the third dopant layer 60 from the source contact 140 to the drain contact 25, thereby creating a shielded source 140.

In one example of the example transistor 10 (junction field-effect transistor) of FIG. 1, the first type dopant may be an n-type dopant and the second type dopant may be a p-type dopant. In another example of the example transistor 10 (junction field-effect transistor) of FIG. 1, the first type dopant may be a p-type dopant and the second type dopant may be an n-type dopant.

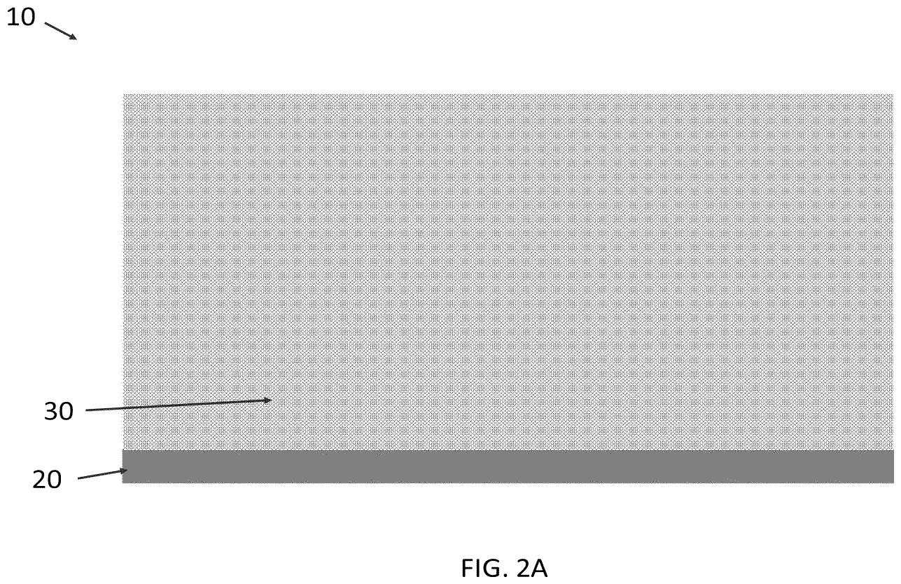

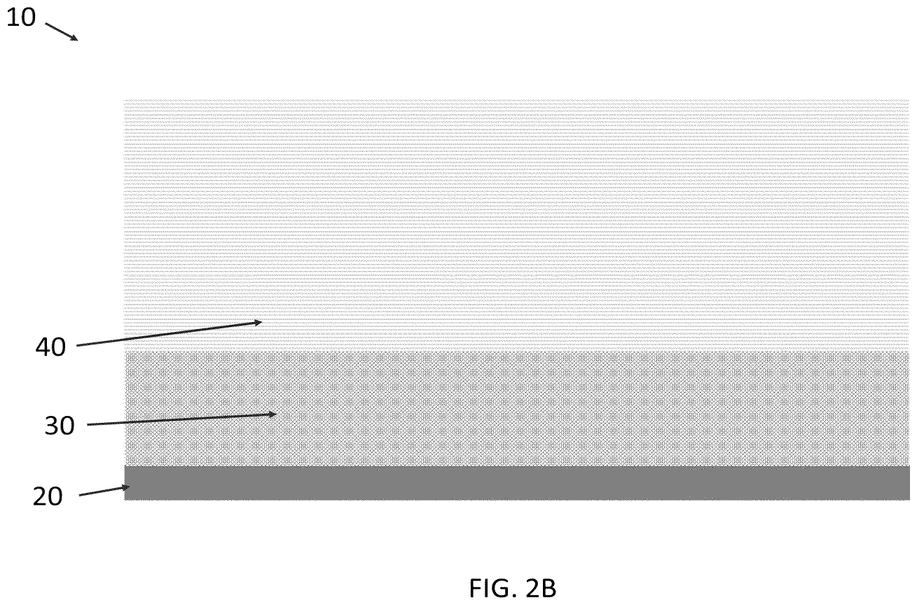

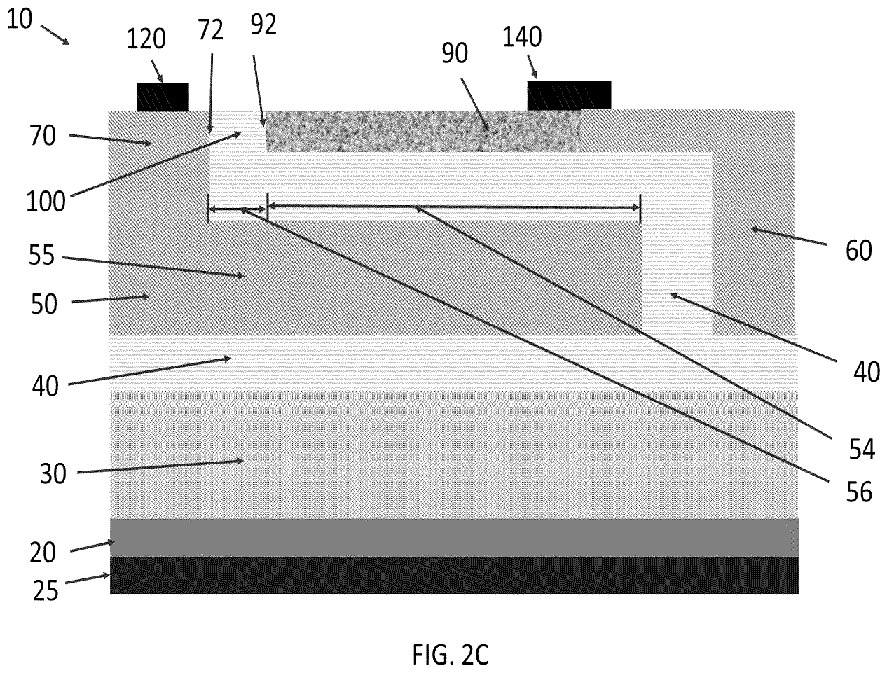

FIGS. 2A-2C show a method of manufacturing a transistor 10 according to one or more examples. Although the example method shown in FIGS. 2A-2C include steps shown in a particular order, the steps may be performed in a different order, and may include additional steps that are not explicitly shown.

FIG. 2A is a cross sectional view of some of the steps in a method of manufacturing a transistor 10 according to one or more examples. Transistor 10 may represent, and may be called a junction field-effect transistor, without limitation. In FIG. 2A, the example method shows a substrate 20 that may have a first concentration of a first type dopant, e.g., 5E18 (i.e. 5×10¹⁸). In FIG. 2A, the method may include forming an epi layer 30 formed within the substrate 20. The epi layer 30 may comprise a second concentration of the first type dopant, wherein the first concentration of first type dopant in the substrate 20 is greater than the second concentration of first type dopant in the epi layer 30.

FIG. 2B is a cross sectional view of some of the steps in a method of manufacturing a transistor 10 according to one or more examples. In FIG. 2B, the method may include implanting a first dopant layer 40 into the epi layer 30. The first dopant layer 40 may comprise a third concentration of the first type dopant.

FIG. 2C is a cross sectional view of some of the steps in a method of manufacturing a transistor 10 according to one or more examples. In the method step shown in FIG. 2C, the method may include implanting a second dopant layer 50 having a lower lateral well extension 55 into the first dopant layer 40. In the method step shown in FIG. 2C, the method may include implanting a third dopant layer 60 into the first dopant layer 40. The second dopant layer 50 and the third dopant layer 60 may comprise a fourth concentration of a second type dopant that may have a peak doping in the range 1E17 to 5E18. In the method step shown in FIG. 2C, the method may include implanting a fourth dopant layer 70 into the first dopant layer 40 and over the second dopant layer 50. The fourth dopant layer 70 may comprise a fifth concentration of the second type dopant. In the method step shown in FIG. 2C, the method may include implanting a fifth dopant layer 90 into the first dopant layer 40. The fifth dopant layer 90 may extend over a first portion 54 of the lower lateral well extension 55. The fifth dopant layer 90 may be operatively connected to the third dopant layer 60. The fifth dopant layer 90 may comprise a sixth concentration of the first type dopant. In the method step shown in FIG. 2C, the method may include forming a planar surface over the fourth dopant layer 70 and the fifth dopant layer 90. In FIG. 2C, the method may include forming a gap 100 formed between an end 92 of the fifth dopant layer 90 and an end 72 of the fourth dopant layer 70. The gap 100 may be formed over a second portion 56 of the lower lateral well extension 55. In FIG. 2C, the method may include forming a gate contact 120 operatively connected to the fourth dopant layer 70. The gate contact 120 may be made from a metal, polysilicon, or other suitable material. In FIG. 2C, the method may include forming a source contact 140 operatively connected to the fifth dopant layer 90. The source contact 140 may be made from a metal, polysilicon, or other suitable material. In FIG. 2C, the method may include forming a drain contact 25 that may be formed on the substrate 20 at an opposite side of the substrate 20 to the epi layer 30. The drain contact 25 may be made from a metal, polysilicon, or other suitable material. When a gate-to-source voltage is applied to the transistor 10 (junction field-effect transistor) of FIG. 2C, current flows through a channel created within the gap 100 and between the lower lateral well extension 55 and the third dopant layer 60 from the source contact 140 to the drain contact 25, thereby creating a shielded source 140.

The example method of manufacturing a transistor 10 of FIGS. 2A-2C may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
an epi layer formed within the substrate;
a first dopant layer formed within the epi layer;
a second dopant layer having a lower lateral well extension formed within the first dopant layer;
a third dopant layer formed within the first dopant layer;
a fourth dopant layer formed within the first dopant layer and over the second dopant layer;
a fifth dopant layer formed within the first dopant layer, wherein the fifth dopant layer extends over a first portion of the lower lateral well extension;
a gap formed between an end of the fifth dopant layer and an end of the fourth dopant layer, wherein the gap extends over a second portion of the lower lateral well extension;
a gate contact operatively connected to the fourth dopant layer; and
a source contact operatively connected to the fifth dopant layer.

2. The transistor of claim 1, wherein the fifth dopant layer operatively connected to the third dopant layer.

3. The transistor of claim 1, wherein the substrate comprises a first concentration of the first type dopant.

4. The transistor of claim 3, wherein the epi layer comprises a second concentration of the first type dopant, the first concentration greater than the second concentration.

5. The transistor of claim 4, wherein the first dopant layer comprises a third concentration of the first type dopant.

6. The transistor of claim 5, wherein the second dopant layer and the third dopant layer comprises a fourth concentration of a second type dopant.

7. The transistor of claim 6, wherein the fourth dopant layer comprises a fifth concentration of the second type dopant.

8. The transistor of claim 7, wherein the fifth dopant layer comprises a sixth concentration of the first type dopant.

9. The transistor of claim 8, wherein the first type dopant comprises an n-type dopant and the second type dopant comprises a p-type dopant.

10. The transistor of claim 8, wherein the first type dopant comprises a p-type dopant and the second type dopant comprises an n-type dopant.

11. A method of manufacturing a transistor, the method comprising:
providing a substrate;
forming an epi layer within the substrate;
implanting a first dopant layer into the epi layer;
implanting a second dopant layer having a lower lateral well extension into the first dopant layer;
implanting a third dopant layer into the first dopant layer;
implanting a fourth dopant layer into the first dopant layer and over the second dopant layer;
implanting a fifth dopant layer into the first dopant layer wherein the fifth dopant layer extends over a first portion of the lower lateral well extension;
forming a gap between an end of the fifth dopant layer and an end of the fourth dopant layer, wherein the gap extends over a second portion of the lower lateral well extension;
forming a gate contact operatively connected to the fourth dopant layer; and
forming a source contact operatively connected to the fifth dopant layer.

12. The method of claim 11, wherein the fifth dopant layer operatively connected to the third dopant layer.

13. The method of claim 11, wherein the substrate comprises a first concentration of the first type dopant.

14. The method of claim 13, wherein the epi layer comprises a second concentration of the first type dopant, the first concentration greater than the second concentration.

15. The method of claim 14, wherein the first dopant layer comprises a third concentration of the first type dopant.

16. The method of claim 15, wherein the second dopant layer and the third dopant layer comprises a fourth concentration of a second type dopant.

17. The method of claim 16, wherein the fourth dopant layer comprises a fifth concentration of the second type dopant.

18. The method of claim 17, wherein the fifth dopant layer comprises a sixth concentration of the first type dopant.

19. The method of claim 18, wherein the first type dopant comprises an n-type dopant and the second type dopant comprises a p-type dopant.

20. The method of claim 18, wherein the first type dopant comprises a p-type dopant and the second type dopant comprises an n-type dopant.
